(19) United States
(12) Patent Application Publication
(10) Pub. No.: US 2024/0290833 A1
(43) Pub. Date: Aug. 29, 2024

(54) SEMICONDUCTOR DEVICE HAVING DEVICE ISOLATION LAYERS

(71) Applicant: Samsung Electronics Co., Ltd., Suwon-si (KR)

(72) Inventors: Minho CHOI, Suwon-si (KR); Kiseok LEE, Suwon-si (KR); Chansic YOON, Suwon-si (KR); Jaybok CHOI, Suwon-si (KR)

(73) Assignee: Samsung Electronics Co., Ltd., Suwon-si (KR)

(21) Appl. No.: 18/537,552

(22) Filed: Dec. 12, 2023

(30) Foreign Application Priority Data
Feb. 28, 2023 (KR) 10-2023-0027137

(51) Int. Cl. H01L 29/06; H01L 29/423; H01L 29/78; H10B 12/00

(52) U.S. Cl. CPC H01L 29/0649; H01L 29/4236; H01L 29/7855; H10B 12/482

(57) ABSTRACT

A semiconductor device includes device isolation layers extending in a first horizontal direction and spaced apart from each other in a second horizontal direction intersecting the first horizontal direction, active regions between the device isolation layers and spaced apart from each other in the first horizontal direction, insulating structures between the active regions, and a gate structure extending in a third horizontal direction between the first horizontal direction and the second horizontal direction and intersecting the active regions, wherein two side surfaces of each active region adjacent to each other define an acute angle, and wherein at least a portion of at least one of the insulating structures is between a corresponding pair of the active regions and between a corresponding pair of the device isolation layers and overlaps the corresponding pair of the active regions in the first horizontal direction.

### CROSS-REFERENCE TO RELATED APPLICATION(S)

This application claims benefit of priority to Korean Patent Application No. 10-2023-0027137 filed on Feb. 28, 2023 in the Korean Intellectual Property Office, the disclosure of which is incorporated herein by reference in its entirety.

### BACKGROUND

Example embodiments of the present disclosure relate to semiconductor devices having device isolation layers.

As demands for high performance, high speed, and/or multifunctionality of a semiconductor device have increased, integration density of a semiconductor device has increased. In manufacturing a semiconductor device having a fine pattern in response to the trend for high integration of a semiconductor device, it may be necessary to implement patterns having a fine width or a fine spacing distance.

### SUMMARY

Some example embodiments of the present disclosure provide semiconductor devices including a device isolation layer and an insulating structure defining an active region.

According to an example embodiment of the present disclosure, a semiconductor device includes a plurality of device isolation layers extending in a first horizontal direction and spaced apart from each other in a second horizontal direction intersecting the first horizontal direction, a plurality of active regions between the plurality of device isolation layers and spaced apart from each other in the first horizontal direction, a plurality of insulating structures between the plurality of active regions, and a gate structure extending in a third horizontal direction between the first horizontal direction and the second horizontal direction and intersecting the plurality of active regions, wherein two adjacent side surfaces of each of the plurality of active regions form an acute angle, and wherein at least a portion of at least one of the plurality of insulating structures is between a corresponding pair of the plurality of active regions and between a corresponding pair of the plurality of device isolation layers and overlaps the corresponding pair of the plurality of active regions in the first horizontal direction.

According to an example embodiment of the present disclosure, a semiconductor device includes a plurality of device isolation layers extending in a first horizontal direction and spaced apart from each other in a second horizontal direction intersecting the first horizontal direction, a plurality of active regions between the plurality of device isolation layers and spaced apart from each other in the first horizontal direction, the plurality of insulating structures between the plurality of active regions, and a gate structure extending in a third horizontal direction between the first horizontal direction and the second horizontal direction and intersecting the plurality of active regions, wherein two adjacent side surfaces of each of the plurality of active regions form an acute angle, wherein at least a portion of at least one of the plurality of insulating structure is between a corresponding pair of the plurality of active regions and between a corresponding pair of the plurality of device isolation layers and overlaps the corresponding pair of the plurality of active regions in the first horizontal direction, wherein the plurality of insulating structures each include an external insulating layer and an internal insulating layer in the external insulating layer, and wherein the external insulating layer is in contact with a corresponding pair of the plurality of active regions and a corresponding pair of the plurality of device isolation layers.

According to an example embodiment of the present disclosure, a semiconductor device includes a first active region and a second active region extending in a first horizontal direction and spaced apart from each other in the first horizontal direction, a first device isolation layer and a second device isolation layer spaced apart from each other in a second horizontal direction intersecting the first horizontal direction, the first device isolation layer and the second device isolation layer extending in the first horizontal direction, the first active region and the second active region interposed between the first device isolation layer and the second device isolation layer, an insulating structure between the first active region and the second active region and in contact with the first active region and the second active region, a gate structure extending in a third horizontal direction between the first horizontal direction and the second horizontal direction and intersecting the first active region, and a bitline structure intersecting the first active region and extending in a fourth horizontal direction orthogonal to the third horizontal direction, wherein a side surface of the first active region in contact with the insulating structure is a curved surface recessed toward a central portion of the first active region, and wherein at least a portion of the insulating structure is between the first active region and the second active region and between the first device isolation layer and the second device isolation layer, and overlaps the first active region in the first horizontal direction.

### BRIEF DESCRIPTION OF DRAWINGS

The above and other aspects, features, and advantages of the present disclosure will be more clearly understood from the following detailed description, taken in combination with the accompanying drawings, in which:

FIGS. 1A to 6C are plan views and vertical cross-sectional views illustrating processes of a method of manufacturing a semiconductor device in order according to an example embodiment of the present disclosure;

FIG. 7 is a diagram illustrating an active region and a contact plug according to an example embodiment of the present disclosure;

FIG. 8A is a plan view illustrating a semiconductor device according to an example embodiment of the present disclosure;

FIG. 8B is a vertical cross-sectional view illustrating a semiconductor device taken along line III-III′ in FIG. 8A;

FIG. 9A is a plan view illustrating a semiconductor device according to an example embodiment of the present disclosure;

FIG. 9B is a vertical cross-sectional view illustrating a semiconductor device taken along line III-III′ in FIG. 9A;

FIG. 10 is a vertical cross-sectional view illustrating a semiconductor device according to an example embodiment of the present disclosure;

FIG. 11 is a plan view illustrating a semiconductor device according to an example embodiment of the present disclosure;

FIGS. 12 and 13 are enlarged diagrams illustrating the semiconductor device illustrated in FIG. 11;

FIGS. 14A to 15B are plan views and vertical cross-sectional views illustrating processes of a method of manufacturing a semiconductor device in order according to an example embodiment of the present disclosure;

FIGS. 16A to 17C are plan views and vertical cross-sectional views illustrating processes of a method of manufacturing a semiconductor device in order according to an example embodiment of the present disclosure; and

FIGS. 18A to 19C are plan views and vertical cross-sectional views illustrating processes of a method of manufacturing a semiconductor device in order according to an example embodiment of the present disclosure.

### DETAILED DESCRIPTION

Hereinafter, some example embodiments of the present disclosure will be described as follows with reference to the accompanying drawings.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

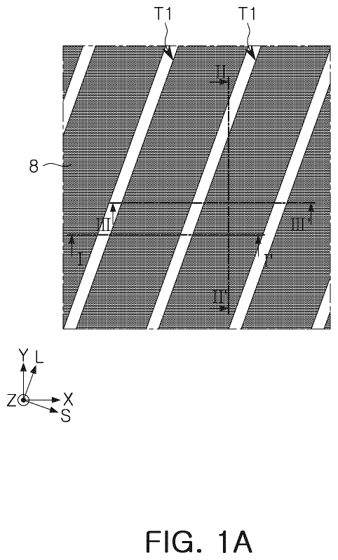

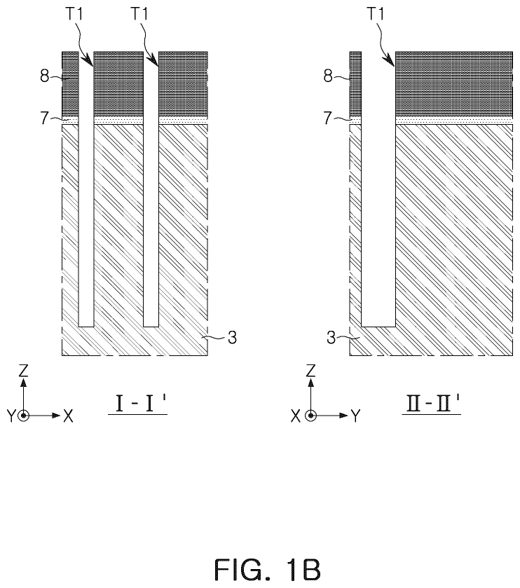

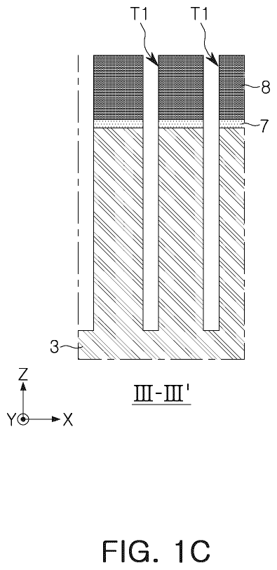

FIGS. 1A to 6C are plan views and vertical cross-sectional views illustrating processes of a method of manufacturing a semiconductor device in order according to an example embodiment. Specifically, FIGS. 1A, 2A, 3A, 4A, 5A and 6A are plan views illustrating processes of a method of manufacturing a semiconductor device in order. FIGS. 1B, 2B, 3B, 4B, 5B and 6B are vertical cross-sectional views taken along lines I-I′ and II-II′ in FIGS. 1A, 2A, 3A, 4A, 5A and 6A, respectively. FIGS. 1C, 2C, 3C, 4C, 5C and 6C are vertical cross-sectional views taken along line III-III′ in FIGS. 1A, 2A, 3A, 4A, 5A and 6A, respectively.

Referring to FIGS. 1A to 1C, a protective layer 7 and a mask layer 8 may be formed on a substrate 3. The substrate 3 may include a semiconductor material, such as a group IV semiconductor, a group III-V compound semiconductor, or a group II-VI compound semiconductor. For example, the group IV semiconductor may include silicon, germanium or silicon-germanium. The substrate 3 may include a silicon substrate, a silicon on insulator (SOI) substrate, a germanium substrate, a germanium on insulator (GOI) substrate, a silicon-germanium substrate, or an epitaxial layer.

The protective layer 7 may cover an upper surface of the substrate 3, and the mask layer 8 may cover an upper surface of the protective layer 7. The protective layer 7 and the mask layer 8 may include silicon oxide, silicon nitride, silicon oxynitride, or a combination thereof. In an example embodiment, the protective layer 7 may include silicon oxide. In an example embodiment, mask layer 8 may include one or more layers. For example, the mask layer 8 may include a silicon oxide layer disposed on a silicon nitride layer.

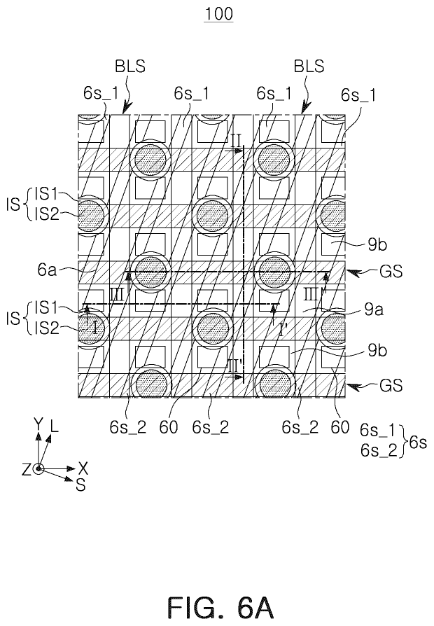

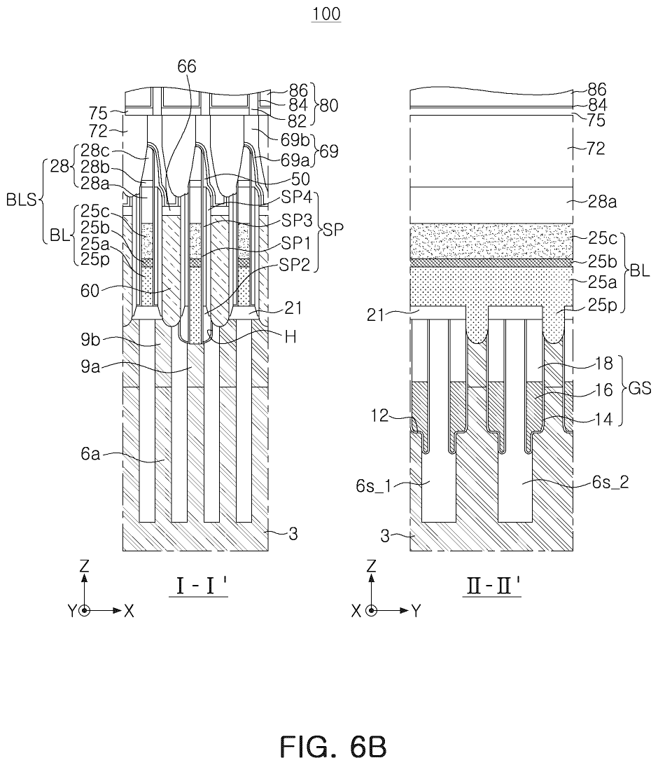

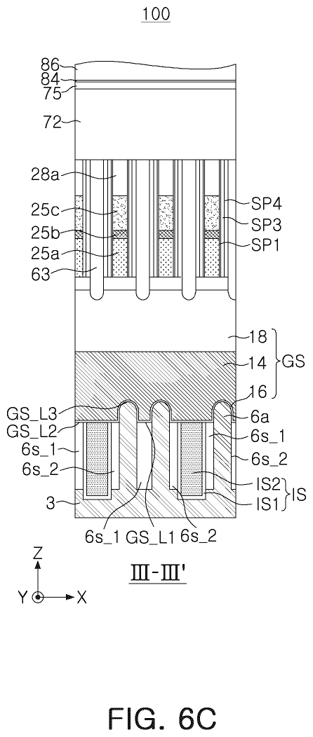

After the protective layer 7 and the mask layer 8 are formed, a first trench T1 may be formed by an anisotropic etching process. The first trenches T1 may extend in the L-direction and may be spaced apart from each other in the X-direction or the S-direction. Here, the L-direction may be a direction between the X-direction and the Y-direction, and may refer to a direction in which the active region 6a in FIG. 6A to be described later extends. The S-direction may refer to a direction orthogonal to the L-direction. The L-direction may be referred to as a major axis-direction of the active region 6a, and the S-direction may be referred to as a thickness-direction of the active region 6a. The first trench T1 may partially penetrate the substrate 3, and may completely penetrate the protective layer 7 and the mask layer 8. The width and pitch of the first trenches T1 in the S-direction may be constant.

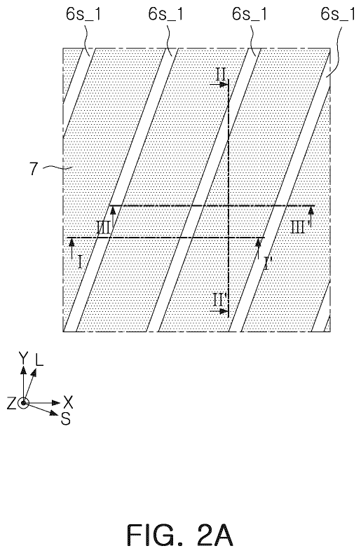

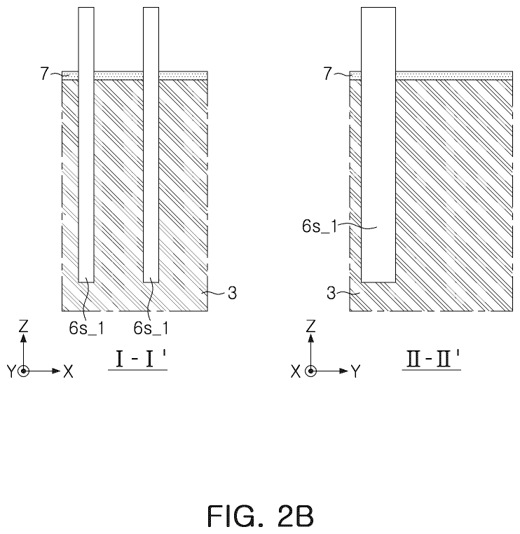

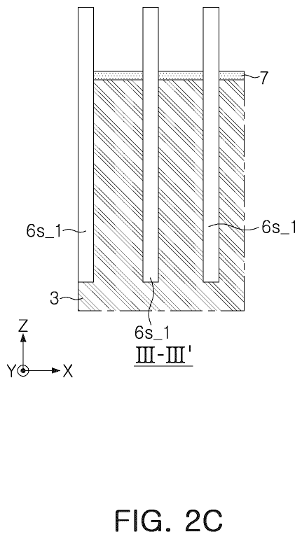

Referring to FIGS. 2A to 2C, a first device isolation layer 6s_1 may be formed in the first trench T1. The first device isolation layer 6s_1 may be formed by forming an insulating material to cover the upper surface of the mask layer 8 while filling the first trench T1, and etching the insulating material through an etching process including at least one of dry etching and wet etching. The first device isolation layers 6s_1 may extend in the L-direction and may be spaced apart from each other in the X-direction or the S-direction. The first device isolation layer 6s_1 may include silicon oxide, silicon nitride, silicon oxynitride, or a combination thereof. In an example embodiment, the first device isolation layer 6s_1 may include silicon oxide.

After the first device isolation layer 6s_1 is formed, the mask layer 8 may be removed. The mask layer 8 may include a material having selectivity with the protective layer 7, and the mask layer 8 may be selectively removed without removing the protective layer 7. In the process of removing the mask layer 8, an upper portion of the first device isolation layer 6s_1 may be partially removed. After the mask layer 8 is removed, the upper portion of the first device isolation layer 6s_1 may protrude from the upper surface of the protective layer 7 in a vertical direction, and the upper portion of the first device isolation layer 6s_1 may be exposed.

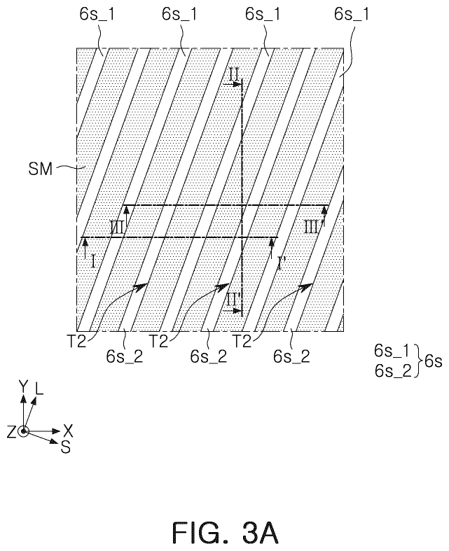

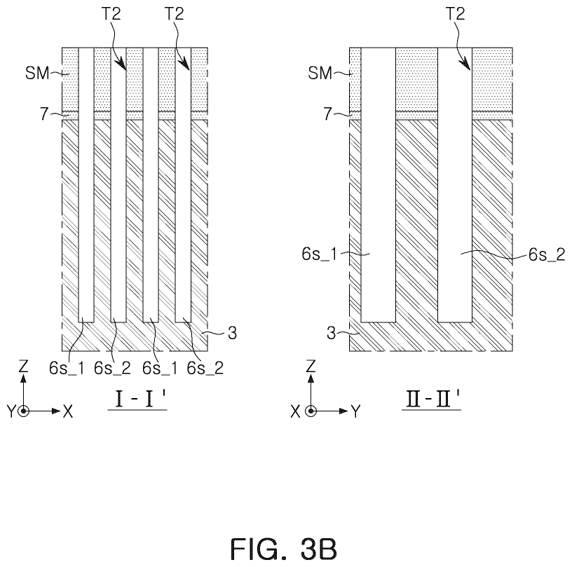

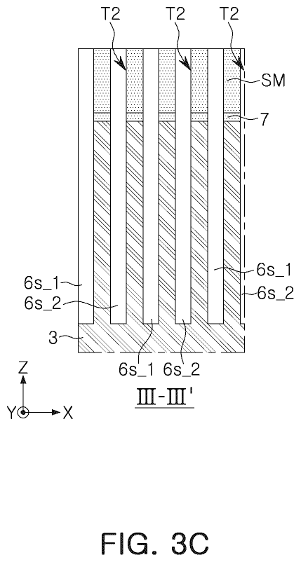

Referring to FIGS. 3a to 3c, a spacer mask SM may be formed on the protective layer 7. The spacer mask SM may be formed by forming an insulating material to cover the protective layer 7 and the first device isolation layer 6s_1 and anisotropically etching the insulating material. A side surface of the exposed portion of the first device isolation layer 6s_1 may be covered by the spacer mask SM. In an example embodiment, the spacer mask SM may include silicon oxide.

After the spacer mask SM is formed, a second trench T2 may be formed. The second trenches T2 may extend in the L-direction and may be spaced apart from each other in the X-direction or the S-direction. The second trench T2 may partially penetrate the substrate 3, and may completely penetrate the protective layer 7 and the spacer mask SM. A width and a pitch of the second trenches T2 in the S-direction may be constant. In an example embodiment, widths in the S-direction and depths in the vertical direction of the first trench T1 and the second trench T2 may be the same, and pitches of the first trench T1 and the second trench 12 may be the same.

After the second trench T2 is formed, a second device isolation layer 6s_2 may be formed in the second trench 12. The second device isolation layer 6s_2 may be formed by forming an insulating material to cover the upper surface of the spacer mask SM while filling the second trench 12, and etching the insulating material through an etching process including at least one of dry etching and wet etching. The second device isolation layers 6s_2 may extend in the L-direction and may be spaced apart from each other in the X-direction or the S-direction. The second device isolation layer 6s_2 may include silicon oxide, silicon nitride, silicon oxynitride, or a combination thereof. In an example embodiment, the second device isolation layer 6s_2 may include silicon oxide. The first device isolation layer 6s_1 and the second device isolation layer 6s_2 may form the device isolation layer 6s. The device isolation layers 6s may be spaced equally apart from each other.

As illustrated in FIGS. 1A to 3C, the first trench T1 and the second trench 12 may be formed by another etching process, and accordingly, the first device isolation layer 6s_1 and the second device isolation layer 6s_2 may be formed by another process. Because the first trench T1 and the second trench 12 are not formed simultaneously, difficulty of the etching process may be reduced. Accordingly, the first device isolation layer 6s_1 and the second device isolation layer 6s_2 may be formed in a finer pattern and may have a deeper depth. Accordingly, electrical shorts between the active regions 6a adjacent to each other in FIG. 6A may be mitigated or prevented, and electrical properties of the semiconductor device 100 may improve. Further, because the second trench 12 is formed after the first device isolation layer 6s_1 is formed in the first trench T1, the pattern on the substrate 3 may be mitigated or prevented from being tilted or merged when the second trench 12 is formed.

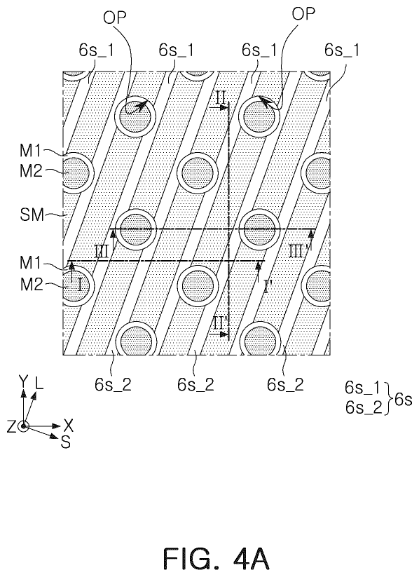

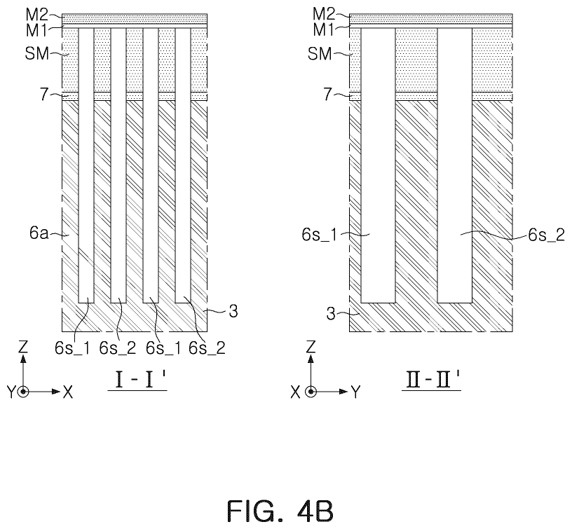

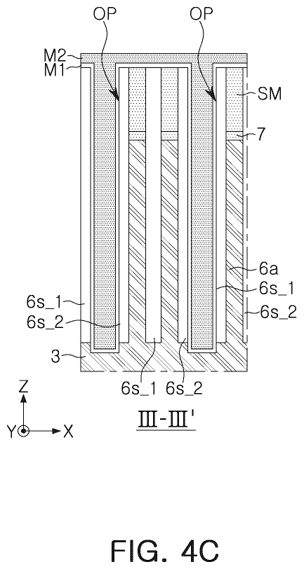

Referring to FIGS. 4A to 4C, an opening OP penetrating through the substrate 3, the protective layer 7 and the spacer mask SM may be formed between the first device isolation layer 6s_1 and the second device isolation layer 6s_2. The opening OP may partially penetrate through the first device isolation layer 6s_1 and the second device isolation layer 6s_2. In the plan view, the opening OP may have a circular shape. However, an example embodiment thereof is not limited thereto, and in some example embodiments, the opening OP may have an elliptical shape or a polygonal shape. Also, in the plan view, side surfaces of the first device isolation layer 6s_1 and the second device isolation layer 6s_2 may be recessed.

A first material layer M1 may be formed on an internal wall of the opening OP, and a second material layer M2 may be formed on the first material layer M1. The first material layer M1 may be conformally formed along the internal wall of the opening OP and may be in contact with the device isolation layer 6s and the substrate 3. The second material layer M2 may fill the opening OP. The first material layer M1 and the second material layer M2 may also cover the spacer mask SM.

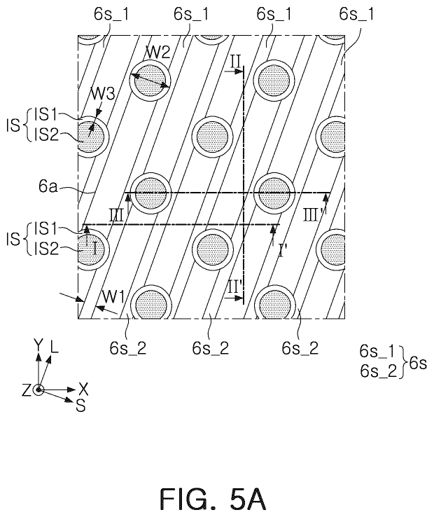

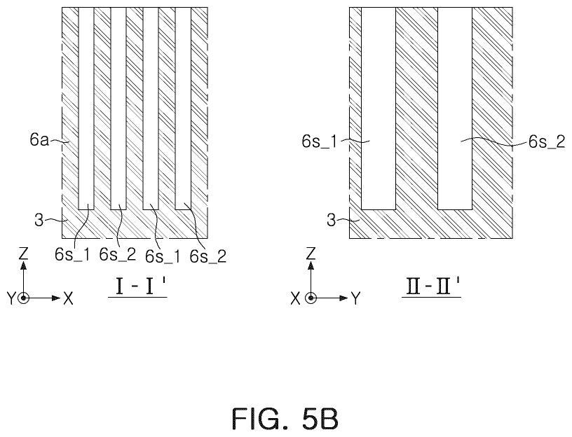

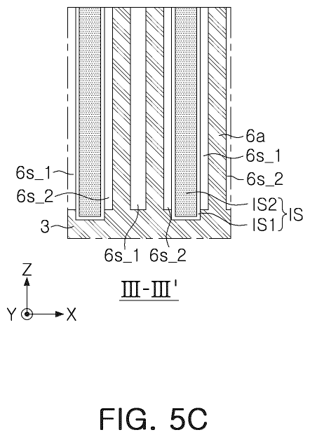

Referring to FIGS. 5A to 5C, an upper surface of the substrate 3 may be exposed by performing an etching process. The etching process may include at least one of dry etching, wet etching, and chemical mechanical polishing CMP. The protective layer 7 and the spacer mask SM may be removed by the etching process, and upper portions of the first device isolation layer 6s_1, the second device isolation layer 6s_2, the first material layer M1 and the second material layer M2 may be removed. The first device isolation layer 6s_1 and the second device isolation layer 6s_2 may be coplanar with the upper surface of the substrate 3.

An external insulating layer IS1 and an internal insulating layer IS2 may be formed by etching the first material layer M1 and the second material layer M2. The external insulating layer IS1 and the internal insulating layer IS2 may form an insulating structure IS. As illustrated in the plan view, the insulating structure IS may be disposed between the first device isolation layer 6s_1 and the second device isolation layer 6s_2, and the upper surface of the insulating structure IS may be coplanar with the upper surface of the substrate 3. In an example embodiment, as illustrated in the plan view, at least a portion of the insulating structure IS may overlap at least one of the first device isolation layer 6s_1 and the second device isolation layer 6s_2 in the X-direction or the S-direction. A horizontal width W2 of the insulating structure IS in the S-direction may be greater than a horizontal width W1 of the device isolation layer 6s in the S-direction. Because the insulating structure IS in the example embodiment is formed in a process different from the process of forming the device isolation layer 6s, the size of the internal insulating layer IS2 may relatively increase. For example, the horizontal width W3 of the external insulating layer IS1 in the S-direction may be less than half of the horizontal width W1 of the device isolation layer 6s in the S-direction. A lower surface of the insulating structure IS of the device isolation layer 6s may be lower than the lower surface of the device isolation layer 6s.

The insulating structure IS may include silicon oxide, silicon nitride, silicon oxynitride, or a combination thereof. In an example embodiment, the external insulating layer IS1 may include silicon oxide, and the internal insulating layer IS2 may include silicon nitride.

The first device isolation layer 6s_1, the second device isolation layer 6s_2 and the insulating structure IS may define an active region 6a. For example, a portion of the substrate 3 surrounded by the first device isolation layer 6s_1, the second device isolation layer 6s_2 and the insulating structure IS may be referred to as an active region 6a. In the plan view, the active region 6a may extend in the L-direction, which is the direction of the major axis, and may have a bar shape. The active regions 6a may be spaced apart from each other in the L-direction and the S-direction. The active region 6a may be in contact with the insulating structures IS that are adjacent to the active region 6a in the L-direction and may be in contact with the first device isolation layer 6s_1 and the second device isolation layer 6s_2 that are adjacent to the active region 6a in the S-direction. In an example embodiment, a horizontal width of the insulating structure IS may be greater than the horizontal width of the active region 6a. For example, a maximum horizontal width of the insulating structure IS may be greater than the horizontal width of the active region 6a in the S-direction.

Referring to FIGS. 6A to 6C, in an example embodiment, impurities regions 9a and 9b may be formed by injecting impurities into the substrate 3. For example, a first impurity region 9a may be formed in a central portion of the active region 6a, and a second impurity region 9b may be formed on each of both ends of the active region 6a. However, in some example embodiments, the first impurity region 9a and the second impurity region 9b may be formed before forming the device isolation layer 6s or in another process.

The first and second impurities regions 9a and 9b may be provided as source/drain regions of a transistor. For example, the first impurity region 9a may correspond to the drain region, and the second impurity region 9b may correspond to the source region. The source region and the drain region may be formed by first and second impurities regions 9a and 9b by doping or ion implantation of substantially the same impurities. The source region and the drain region may be referred to interchangeably depending on the circuit configuration of the finally formed transistor. The first and second impurities regions 9a and 9b may include impurities having a conductivity type opposite to that of the substrate 3. For example, active regions 6a may include P-type impurities, and the first and second impurities regions 9a and 9b may have N-type impurities.

Thereafter, gate trenches 12 may be formed by anisotropically etching the substrate 3. The gate trenches 12 may extend in the X-direction and may intersect the active region 6a and the device isolation layer 6s. A gate structure GS may be formed by forming a gate dielectric layer 14, a gate electrode 16, and a gate capping layer 18 in the gate trench 12. The gate dielectric layer 14 may be conformally formed on an internal wall of the gate trench 12. The gate electrode 16 may be formed by forming a conductive material on the gate dielectric layer 14 and recessing the conductive material. The gate capping layer 18 may be formed by forming an insulating material on the gate electrode 16 to fill the gate trench 12 and performing a planarization process. An upper surface of the gate capping layer 18 may be coplanar with an upper surface of the device isolation layer 6s.

In an example embodiment, as illustrated in FIG. 6C, the depth of the gate structure GS may not be constant. For example, the lower surface of the gate structure GS may include a first portion GS_L1 in contact with the first device isolation layer 6s_1, a second portion GS_L2 in contact with the first device isolation layer 6s_1, the second device isolation layer 6s_2 and the insulating structure IS, and a third portion GS_L3 in contact with the active region 6a. A horizontal width of the second portion GS_L2 in the X-direction may be greater than a horizontal width of the first portion GS_L1 in the X-direction.

When the gate trench 12 is formed, the gate trench 12 may be formed relatively deeply in a region in which the insulating material layer is disposed relatively wide. For example, the gate trench 12 may be formed relatively shallow in a position corresponding to the device isolation layer 6s and may be formed relatively deeply in a position corresponding to the insulating structure IS. However, the internal insulating layer IS2 may be etched relatively less than the external insulating layer IS1, and as described above, the internal insulating layer IS2 of the insulating structure IS in an example embodiment may be formed to be relatively large. Accordingly, the gate trench 12 may be mitigated or prevented from being formed relatively deeply in a position corresponding to the insulating structure IS. For example, the first portion GS_L1 of the lower surface of the gate structure GS may be disposed on the same level as a level of the second portion GS_L2 of the lower surface of the gate structure GS.

In the plan view, the gate structures GS may extend in the X-direction and may be spaced apart from each other in the Y-direction. Also, the gate structures GS may intersect the active region 6a. For example, two gate structures GS may intersect one active region 6a. Transistors each including the gate structure GS and the first and second impurity regions 9a and 9b may be included in a buried channel array transistor (BCAT), but example embodiments thereof are not limited thereto.

The gate dielectric layer 14 may include silicon oxide or a material having a high dielectric constant. In some example embodiments, the gate dielectric layer 14 may be formed by oxidation of the active region 6a or may be formed by deposition. The gate electrode 16 may include a conductive material, for example, at least one of polycrystalline silicon (Si), titanium (Ti), titanium nitride (TiN), tantalum (Ta), tantalum nitride (TaN), tungsten (W), tungsten nitride (WN), and aluminum (Al). The gate capping layer 18 may include silicon nitride.

A buffer layer 21, a bitline structure BLS and a spacer structure SP may be formed on the substrate 3. The buffer layer 21 may be formed on the upper surfaces of the substrate 3, the active region 6a, the device isolation layer 6s and the gate structure GS. The buffer layer 21 may be formed as a single layer or a plurality of layers.

A bitline structure BLS may be formed on the buffer layer 21. The bitline structure BLS may be formed by forming a contact hole H by etching the buffer layer 21 to expose the active region 6a, stacking conductive material layers on the contact hole H, forming insulating material layers on the conductive material layers, and patterning the conductive material layers and the insulating material layers. The bitline structures BLS may extend in the Y-direction and may be spaced apart from each other in the X-direction from each other.

The bitline structure BLS may include a bitline BL including a conductive material and a bitline capping layer 28 including an insulating material. The bitline BL may include a first conductive layer 25a, a second conductive layer 25b and a third conductive layer 25c stacked in order, and the first conductive layer 25a may include a plug portion 25p disposed in the contact hole H. The bitline capping layer 28 may include a first insulating layer 28a, a second insulating layer 28b, and a third insulating layer 28c stacked in order on the bitline BL. A side surface of the first insulating layer 28a may be coplanar with the first conductive layer 25a, the second conductive layer 25b and the third conductive layer 25c.

The first conductive layer 25a may include polysilicon. The second conductive layer 25b may include a metal-semiconductor compound. The metal-semiconductor compound may be obtained, for example, by siliciding a portion of the first conductive layer 25a. For example, the metal-semiconductor compound may include cobalt silicide (CoSi), titanium silicide (TiSi), nickel silicide (NiSi), tungsten silicide (WSi), or other metal silicides, or may include nitrides such as TiSiN. The third conductive layer 25c may include metal materials such as titanium (Ti), tantalum (Ta), tungsten (W), and aluminum (Al). The bitline BL may further include a plug portion 25p disposed below the first conductive layer 25a, extending downwardly, and in contact with the first impurities region 9a. The plug portion 25p may be disposed in a contact hole H formed on the upper surface of the substrate 3. In the plan view, the plug portion 25p may be in contact with the central portion of the active region 6a. The plug portion 25p may electrically connect the active region 6a to the bitline structure BLS. The plug portion 25p may include the same material as that of the first conductive layer 25a.

The first insulating layer 28a, the second insulating layer 28b and the third insulating layer 28c may include silicon oxide, silicon nitride, silicon oxynitride, or a combination thereof, for example, silicon nitride.

The spacer structure SP may be formed on both side surfaces of the bitline structure BLS. The spacer structure SP may include a first spacer SP1, a second spacer SP2, a third spacer SP3 and a fourth spacer SP4. The first spacer SP1 may be formed by conformally depositing an insulating material along a side surface of the bitline structure BLS and an internal wall of the contact hole H. The second spacer SP2 may be formed by depositing an insulating material on the first spacer SP1 to fill the contact hole H. The third spacer SP3 and the fourth spacer SP4 may be formed by forming an insulating material to cover side surfaces of the second spacer SP2 and the third spacer SP3, respectively, and etching the insulating material. The spacer structure SP may extend in the Y-direction along the side surfaces of the bitline structure BLS.

The first spacer SP1, the second spacer SP2, the third spacer SP3 and the fourth spacer SP4 may include silicon oxide, silicon nitride, silicon oxynitride, or a combination thereof. The spacer structure SP in this example embodiment is merely an example, and the number of materials and the number of layers according to example embodiments are not limited thereto and may be varied.

After the spacer structure SP is formed, a process of etching the buffer layer 21 may be performed to expose the upper surface of the active region 6a. The spaces between the bitline structures BLS may be referred to as trenches. For example, the trench may be defined by opposing side surfaces of spacer structures SP adjacent to each other and may extend in the Y-direction.

A contact plug 60 may be formed in the trench. The contact plug 60 may be formed by filling the trench with a conductive material to cover the spacer structure SP and etching back the conductive material. An upper surface of the contact plug 60 may be disposed on a lower level than the upper end of the bitline structure BLS. The contact plug 60 may be in contact with the upper surface of the active region 6a and may partially fill a space between the spacer structures SP. Thereafter, a portion of the spacer structure SP may be etched by an etching process. For example, upper portions of the first spacer SP1, the third spacer SP3 and the fourth spacer SP4 may be partially removed. The contact plug 60 may be electrically connected to the active region 6a, for example, the second impurities region 9b.

The contact plug 60 may be formed of a conductive material, and may include, for example, at least one of polysilicon (Si), titanium (Ti), titanium nitride (TiN), tantalum (Ta), tantalum nitride (TaN), tungsten (W), tungsten nitride (WN), and aluminum (Al). In an example embodiment, the contact plug 60 may include doped polysilicon and may include N-type impurities such as phosphorus (P), arsenic (As) and antimony (Sb).

In an example embodiment, after the contact plug 60 is formed, a fence structure 63 may be formed as illustrated in FIG. 6C. The fence structure 63 may be formed by removing a portion of the contact plug 60 and filling the space from which the portion of the contact plug 60 is removed with an insulating material. The fence structures 63 may be formed to overlap the gate structure GS between the bitline structures BLS in the vertical direction. The fence structures 63 may be spaced apart from each other in X-direction and Y-direction. For example, the contact plugs 60 may be alternately disposed with the fence structures 63 in the Y-direction between the bitline structures BLS. The fence structures 63 may spatially isolate the contact plugs 60 from each other and may electrically insulate the contact plugs 60 from each other.

The fence structure 63 may have a rod shape or a columnal shape extending in a vertical direction. The lower surface of the fence structure 63 may be in contact with the gate capping layer 18 of the gate structure GS. In an example embodiment, the lower surface of the fence structure 63 may have a curved surface, which is curved downwardly (e.g., convex) toward the gate capping layer 18, and the upper surface of the gate capping layer 18 may have a curved surface, which is curved upwardly (e.g., concave). The lower surface of the fence structure 63 may be disposed on a lower level than the upper surface of the substrate 3. The fence structure 63 may include an insulating material, for example silicon nitride. In some example embodiments, the process of forming the fence structure 63 may be performed prior to the process of forming the contact plug 60.

A barrier material layer and a metal material layer may be formed on a bitline structure BLS, a spacer structure SP and a contact plug 60. A barrier layer 69a and a metal layer 69b may be formed by patterning the barrier material layer and the metal material layer, and the barrier layer 69a and the metal layer 69b may form a landing pad 69. An insulating pattern 72 may be formed by filling an insulating material between the landing pads 69. A metal-semiconductor compound layer 66 may be formed between the contact plug 60 and the landing pad 69. The metal-semiconductor compound layer 66 may be formed by siliciding a portion of the contact plug 60. The landing pad 69 may be disposed on the metal-semiconductor compound layer 66 and may cover the bitline structure BLS and the spacer structure SP. The landing pad 69 may be electrically connected to the second impurities region 9b of the active region 6a through the contact plug 60. The metal-semiconductor compound layer 66 may include cobalt silicide (CoSi), titanium silicide (TiSi), nickel silicide (NiSi), tungsten silicide (WSi), or other metal silicide. The barrier layer 69a may include a metal nitride, for example, at least one of titanium nitride (TiN), tantalum nitride (TaN), and tungsten nitride (WN). The metal layer 69b may include a conductive material, for example, at least one of titanium (Ti), tantalum (Ta), tungsten (W), and aluminum (Al).

The upper surface of the insulating pattern 72 may be coplanar with the upper surface of the landing pad 69, and the insulating pattern 72 may extend downwardly and may be partially in contact with the bitline structures BLS. The insulating pattern 72 may spatially isolate the landing pads 69 from each other and may electrically insulate the landing pads 69 from each other. The insulating pattern 72 may include silicon nitride.

In an example embodiment, before the landing pad 69 is formed, an upper insulating spacer 50 covering the upper portion of the bitline structure BLS and an upper insulating spacer 50 covering the upper portion of the spacer structure SP may be further formed. The barrier layer 69a may conformally cover the upper insulating spacer 50.

The semiconductor device 100 may be manufactured by forming an etch stop layer 75 and a capacitor structure 80 on the landing pad 69. The etch stop layer 75 may cover upper surfaces of the landing pad 69 and the insulating pattern 72. The capacitor structure 80 may include a lower electrode penetrating through the etch stop layer 75 and connected to the landing pad 69, a capacitor dielectric layer on the lower electrode, and an upper electrode on the capacitor dielectric layer.

The capacitor structure 80 may be electrically connected to the landing pad 69 and the contact plug 60. The lower electrode and the upper electrode may include at least one of a doped semiconductor, a metal nitride, a metal, and a metal oxide. The lower electrode and the upper electrode may include, for example, at least one of polycrystalline silicon, titanium nitride (TiN), tungsten (W), titanium (Ti), ruthenium (Ru), and tungsten nitride (WN). The capacitor dielectric layer may include at least one of high dielectric constant materials such as zirconium oxide (ZrO₂), aluminum oxide (Al₂O₃), and hafnium oxide (Hf₂O₃).

The semiconductor device 100 according to an example embodiment may be applied to, for example, a cell array of dynamic random access memory (DRAM), but example embodiments thereof are not limited thereto.

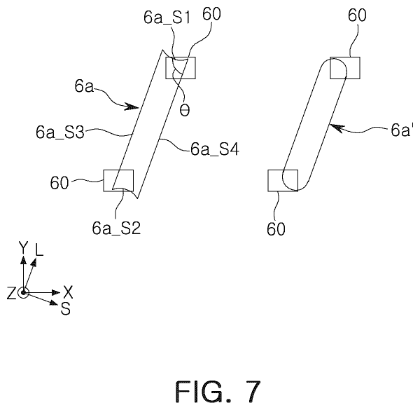

FIG. 7 is a diagram illustrating an active region and a contact plug according to an example embodiment. Specifically, FIG. 7 illustrates an active region 6a and contact plugs 60 in an example embodiment, and an active region 6a′ and contact plugs 60 of the prior art.

Referring to FIGS. 6 and 7, since the insulating structure IS in an example embodiment is formed in a process different from the process of forming the first device isolation layer 6s_1 and the second device isolation layer 6s_2, when forming the insulating structure IS, the active region 6a may not be excessively etched, and accordingly, the size of the active region 6a may relatively increase. For example, the area in which the active region 6a in the example embodiment is in contact with the contact plug 60 may be larger than the area in which the active region 6a′ of the prior art is in contact with the contact plug 60. Accordingly, in the example embodiment, contact resistance between the active region 6a and the contact plug 60 may be lowered and electrical properties of the semiconductor device 100 may be improved.

Further, in an example embodiment, the side surface of the active region 6a may include a inwardly curved surface. For example, the side surface of the active region 6a may include a first side surface 6a_S1, a second side surface 6a_S2, a third side surface 6a_S3 and a fourth side surface 6a_S4. The first side surface 6a_S1 and the second side surface 6a_S2 may oppose each other and may be spaced apart from each other in the L-direction, and the third side surface 6a_S3 and the fourth side surface 6a_S4 may oppose each other and may be spaced apart from each other in the S-direction. The first side surface 6a_S1 and the second side surface 6a_S2 may be curved surfaces recessed toward a central portion of the active region 6a. The third side surface 6a_S3 and the fourth side surface 6a_S4 may extend in the L-direction and may be perpendicular to the S-direction. The first side surface 6a_S1 and the second side surface 6a_S2 may be in contact with insulating structures IS, and the third side surface 6a_S3 and the fourth side surface 6a_S4 may be in contact with the device isolation layer 6s. In an example embodiment, two side surfaces of the active region 6a adjacent to each other may form an acute angle. For example, the angle θ between the first side surface 6a_S1 and the fourth side surface 6a_S4 may be 90 degrees or less.

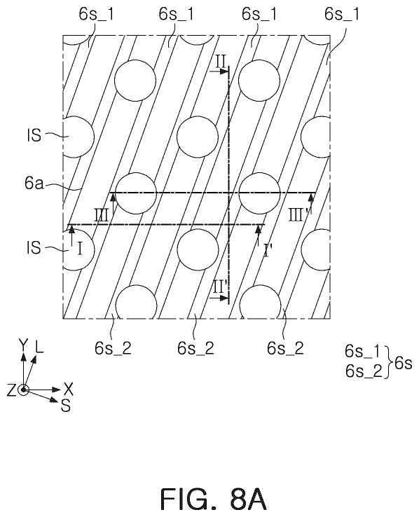

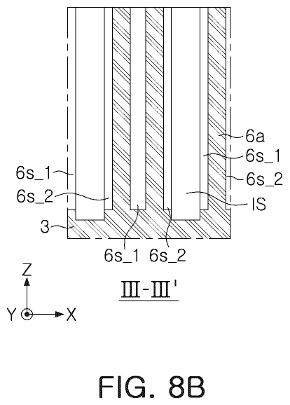

FIG. 8A is a plan view illustrating a semiconductor device according to an example embodiment. FIG. 8B is a vertical cross-sectional view illustrating a semiconductor device taken along line III-III′ in FIG. 8A.

Referring to FIGS. 8A and 8B, in the process of forming the insulating structure IS described with reference to FIGS. 4A to 5C, the insulating structure IS may be formed as a single layer. For example, the insulating structure IS may be configured as a single layer including silicon oxide. Subsequently, processes described with reference to FIGS. 6A to 6C may be further performed, and the semiconductor device 100 may include an insulating structure IS having a single layer.

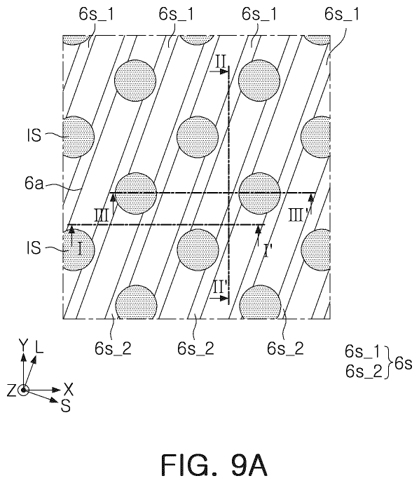

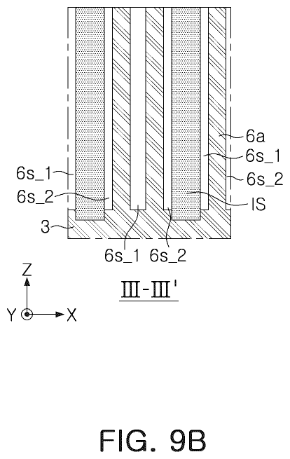

FIG. 9A is a plan view illustrating a semiconductor device according to an example embodiment. FIG. 9B is a vertical cross-sectional view illustrating a semiconductor device taken along line III-III′ in FIG. 9A.

Referring to FIGS. 9A and 9B, in the process of forming the insulating structure IS described with reference to FIGS. 4A to 5C, the insulating structure IS may be formed as a single layer. For example, the insulating structure IS may be a single layer including silicon nitride. Subsequently, the process described with reference to FIGS. 6A to 6C may be further performed, and the semiconductor device 100 may include an insulating structure IS having a single layer.

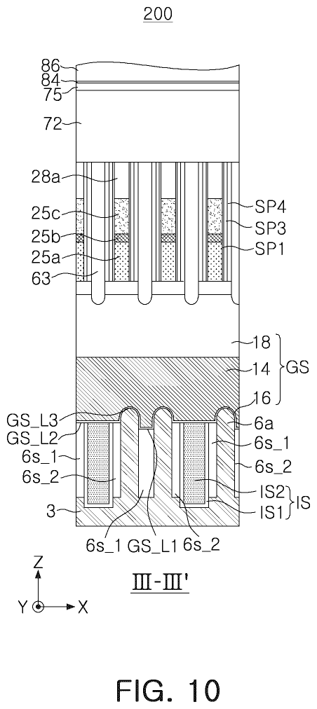

FIG. 10 is a vertical cross-sectional view illustrating a semiconductor device according to an example embodiment.

Referring to FIG. 10, the semiconductor device 200 may include a gate structure GS intersecting the active region 6a, the first device isolation layer 6s_1, the second device isolation layer 6s_2 and the insulating structure IS. When the gate structure GS is formed, the internal insulating layer IS2 including silicon nitride may be etched relatively less than silicon oxide. In an example embodiment, the second portion GS_L2 of the lower surface of the gate structure GS may be disposed on a higher level than the first portion GS_L1 of the lower surface of the gate structure GS.

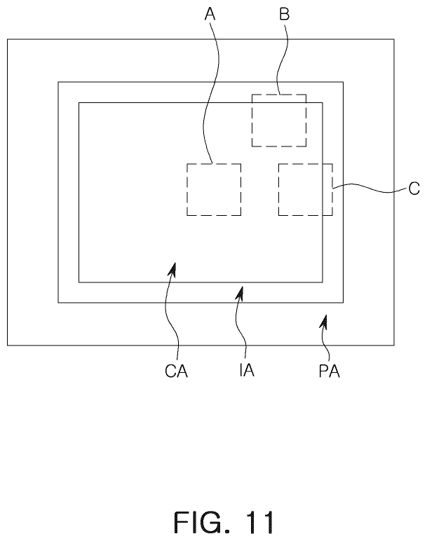

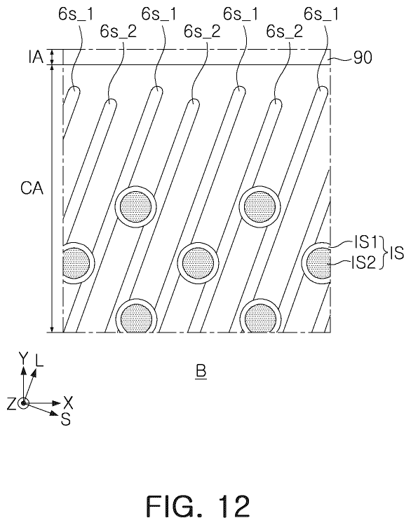

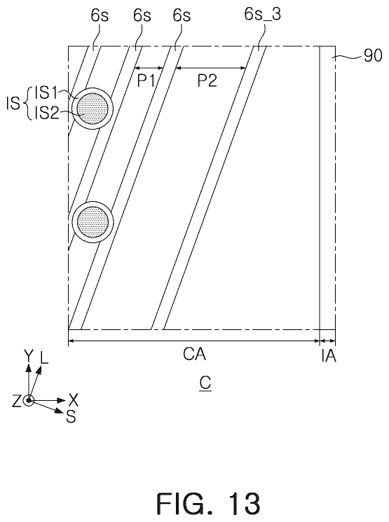

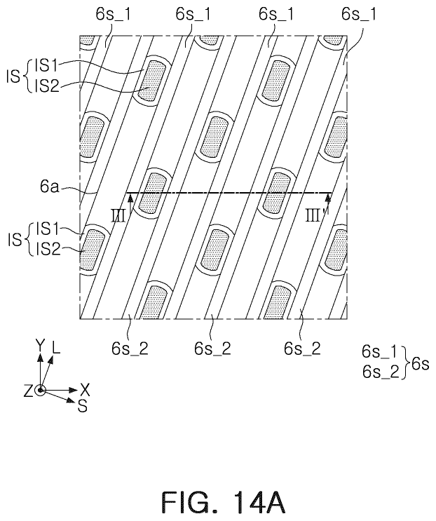

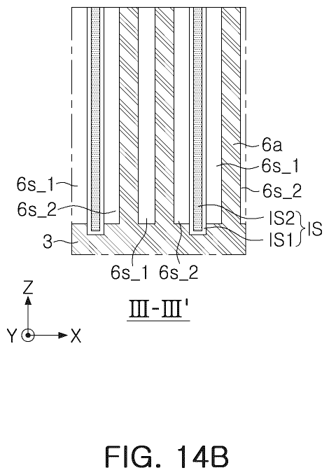

FIG. 11 is a plan view illustrating a semiconductor device according to an example embodiment. FIGS. 12 and 13 are enlarged diagrams illustrating the semiconductor device illustrated in FIG. 11. Specifically, FIG. 12 is an enlarged diagram illustrating region B illustrated in FIG. 11. FIG. 13 is an enlarged diagram illustrating region C illustrated in FIG. 11.

Referring to FIG. 11, a semiconductor device 100 may include a cell region CA, an interface region IA, and a peripheral circuit region PA. The peripheral circuit region PA may be disposed to surround the cell region CA, and the interface region IA may be disposed between the cell region CA and the peripheral circuit region PA. A cell region CA may refer to a region in which memory cells of a DRAM device are disposed, and the interface region IA may refer to a region between the peripheral circuit region PA, in which a row decoder and a sense amplifier are disposed, and the cell region CA. The plan view illustrated in FIG. 6A may be included in region A of the cell region CA.

Referring to FIG. 12, a first device isolation layer 6s_1 and a second device isolation layer 6s_2 may be disposed in the cell region CA. Because the first device isolation layer 6s_1 and the second device isolation layer 6s_2 are formed in different processes, the length of the first device isolation layer 6s_1 in the L-direction may be different from the length of the second device isolation layer 6s_2 in the L-direction. For example, ends in the L-direction (or ends in the Y-direction) of the first device isolation layer 6s_1 and the second device isolation layer 6s_2 may be disposed in a zigzag pattern. In FIG. 12, the end in the L-direction of the first device isolation layer 6s_1 may be disposed closer to the interface region IA than the end in the L-direction of the second device isolation layer 6s_2, but example embodiments thereof are not limited thereto. In some example embodiments, the end in the L-direction of the second device isolation layer 6s_2 may be disposed closer to the interface region IA than the end in the L-direction of the first device isolation layer 6s_1.

In an example embodiment, the semiconductor device 100 may further include a region isolation layer 90 disposed in the interface region IA. The region isolation layer 90 may be formed by forming a trench on the substrate 3 and filling the trench with an insulating material. In an example embodiment, the region isolation layer 90 may be formed simultaneously with the insulating structure IS.

Referring to FIG. 13, a device isolation layer 6s may be disposed in the cell region CA. The device isolation layer 6s may include a first device isolation layer 6s_1 and a second device isolation layer 6s_2 alternately disposed in the X-direction, and may further include a third device isolation layer 6s_3. The third device isolation layer 6s_3 may refer to the layer disposed in an outermost portion in the X-direction among the device isolation layers 6s. As illustrated in FIGS. 1A to 3C, because the first trench T1 and the second trench T2 in which the device isolation layer 6s is formed may be formed in different processes, a portion of the device isolation layers 6s may be formed with a different distance therebetween. Among the device isolation layers 6s, the distance between the third device isolation layer 6s_3 and the most closest layer may be twice the distance between device isolation layers 6s adjacent to each other. For example, the distance P2 in the X-direction between the third device isolation layer 6s_3 and the closest layer among the device isolation layers 6s may be twice the pitch P1 between the device isolation layers 6s.

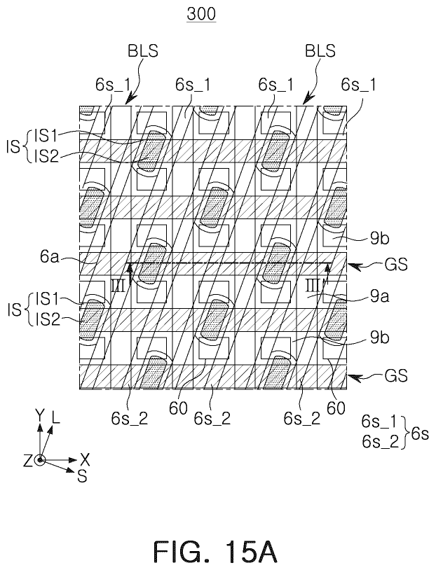

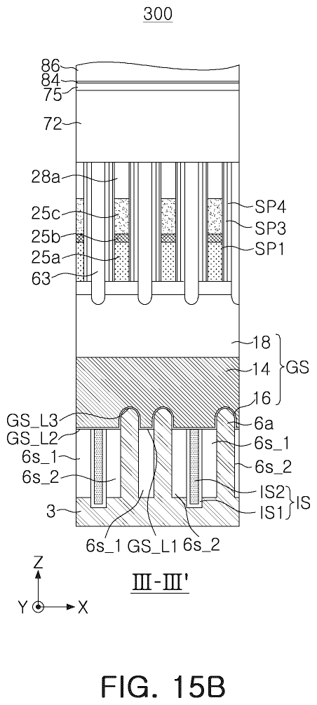

FIGS. 14A to 15B are plan views and vertical cross-sectional views illustrating processes of a method of manufacturing a semiconductor device in order according to an example embodiment. FIGS. 14B and 15B are vertical cross-sectional views taken along line III-III′ in FIGS. 14a and 15a, respectively.

Referring to FIGS. 14A and 14B, in the process described with reference to FIGS. 4A to 5C, an insulating structure IS may be formed between the device isolation layers 6s. For example, in the etching process for forming the opening OP illustrated in FIG. 4A, the substrate 3 may be selectively etched, and the first device isolation layer 6s_1 and the second device isolation layer 6s_2 may not be etched. Accordingly, the insulating structure IS may not overlap the first device isolation layer 6s_1 and the second device isolation layer 6s_2 in the L-direction. In the plan view, horizontal widths of the first device isolation layer 6s_1 and the second device isolation layer 6s_2 may be constant, and side surfaces of the first device isolation layer 6s_1 and the second device isolation layer 6s_2 may not have a recess region. The insulating structure IS may extend in the L-direction, and a portion of the external insulating layer IS1 may extend along surfaces of the first device isolation layer 6s_1 and the second device isolation layer 6s_2. The maximum horizontal width of the insulating structure IS in the S-direction may be the same as a distance between the first device isolation layer 6s_1 and the second device isolation layer 6s_2 adjacent to each other, taken in the S-direction. The shape of the insulating structure IS illustrated in FIG. 14A is merely an example, and in some example embodiments, in a plan view, the insulating structure IS may have a circular shape, an elliptical shape, or a rectangular shape.

Referring to FIGS. 15A and 15B, the process described with reference to FIGS. 6A to 6C may be further performed, and a semiconductor device 300 may be manufactured. The semiconductor device 300 may have a structure the same as or similar to that of the semiconductor device 100 in FIG. 6A to 6C other than the insulating structure IS. In the cross-sectional view, the insulating structure IS may be disposed between the first device isolation layer 6s_1 and the second device isolation layer 6s_2, and horizontal widths in the X-direction or the S-direction of the first device isolation layer 6s_1 and the second device isolation layer 6s_2 may be the same. In some example embodiments, the insulating structure IS of the semiconductor device 300 may have the same structure as the insulating structure IS described with reference to FIGS. 8A to 9B. For example, the insulating structure IS of the semiconductor device 300 may be a single layer including silicon oxide or silicon nitride.

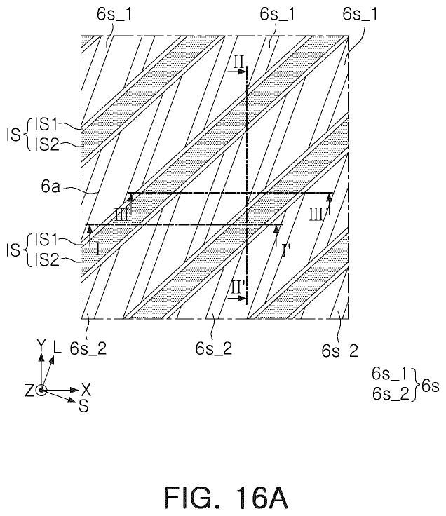

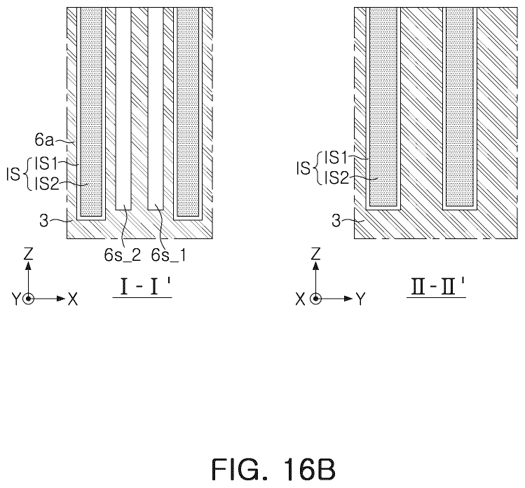

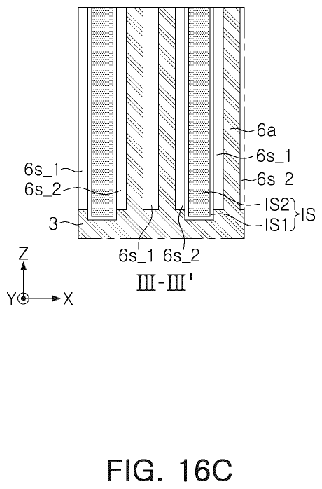

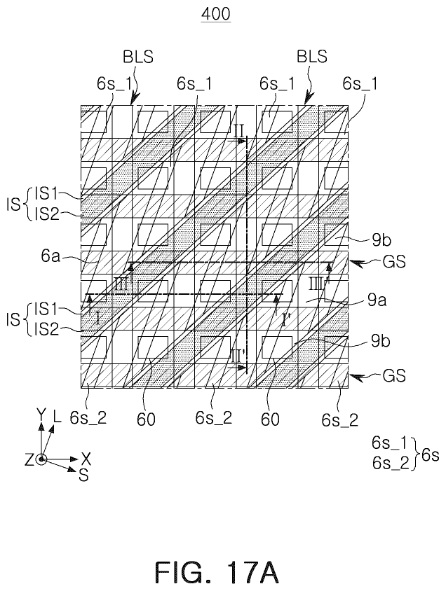

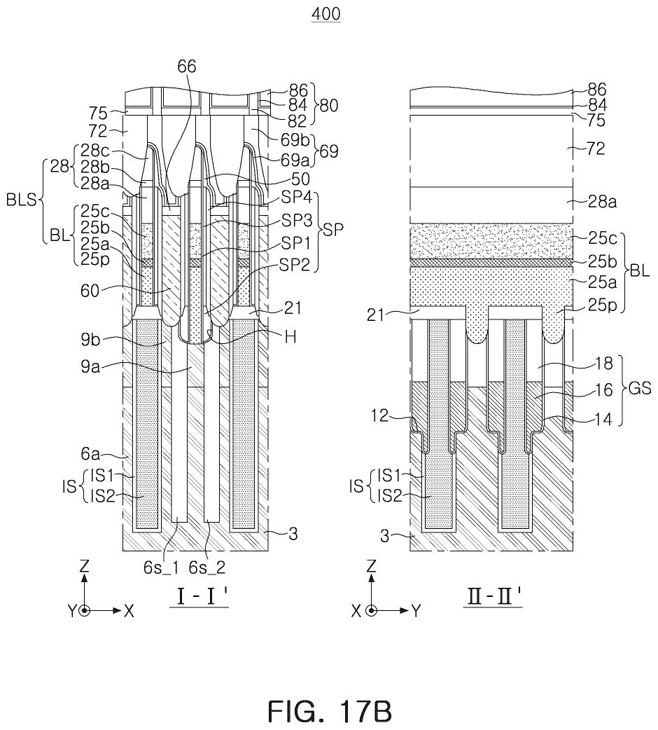

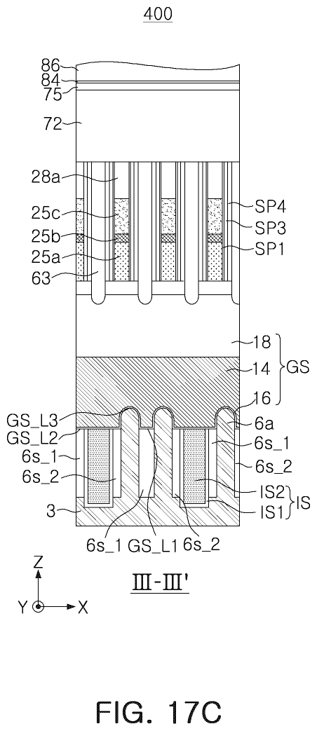

FIGS. 16A to 17C are plan views and vertical cross-sectional views illustrating processes of a method of manufacturing a semiconductor device in order according to an example embodiment. FIGS. 16B and 17B are vertical cross-sectional views along lines I-I′ and II-II′ in FIGS. 16A and 17A, respectively. FIGS. 16C and 17C are vertical cross-sectional views along III-III′ in FIGS. 16A and 17A, respectively.

Referring to FIGS. 16A to 16C, in the process described with reference to FIGS. 4A to 5C, an insulating structure IS may be formed to intersect the device isolation layers 6s. For example, in an etching process for forming the openings OP illustrated in FIG. 4A, the openings OP may be formed to extend in a horizontal direction. Accordingly, a portion of the insulating structure IS may be disposed between the first device isolation layer 6s_1 and the second device isolation layer 6s_2, and a portion of the insulating structure IS may overlap the first device isolation layer 6s_1 and the second device isolation layer 6s_2 in the L direction. In the plan view, the insulating structure IS may extend in a direction between the L-direction and the S-direction and may have a bar shape. As illustrated in the plan view, the first device isolation layer 6s_1 and the second device isolation layer 6s_2 may be cut out by the insulating structure IS.

In the plan view, the active region 6a may have a rhombic shape having a long side and a short side and extending in the L-direction. Two side surfaces of the active region 6a adjacent to each other may form an acute angle.

Referring to FIGS. 17A to 17C, the process described with reference to FIGS. 6A to 6C may be further performed, and a semiconductor device 400 may be manufactured. The semiconductor device 400 may have a structure the same as or similar to that of the semiconductor device 100 other than the insulating structure IS. In the cross-sectional view, the insulating structure IS may vertically penetrate at least a portion of the first device isolation layer 6s_1 and the second device isolation layer 6s_2. Horizontal widths in the X-direction or the S-direction of the first device isolation layer 6s_1 and the second device isolation layer 6s_2 may not be constant. In some example embodiments, the insulating structure IS of the semiconductor device 400 may have the same structure as the insulating structure IS described with reference to FIGS. 8A to 9B. For example, the insulating structure IS of the semiconductor device 400 may be a single layer including silicon oxide or silicon nitride.

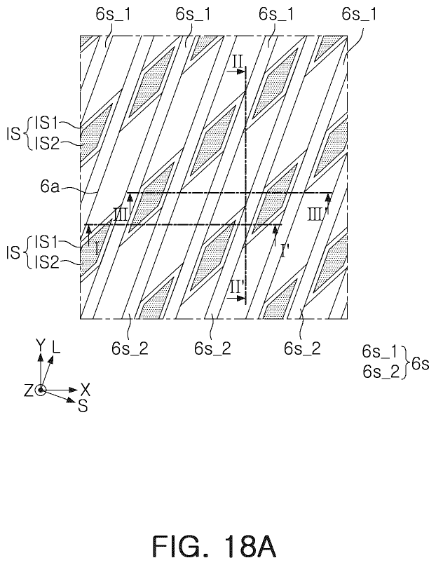

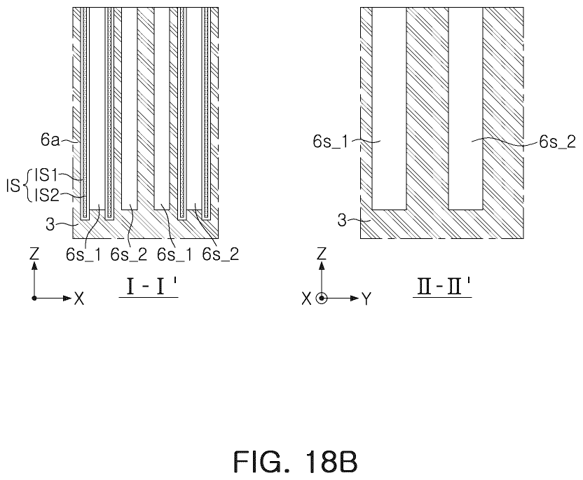

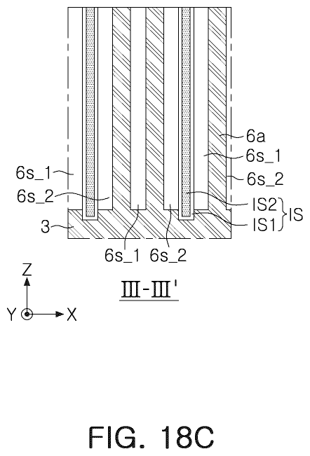

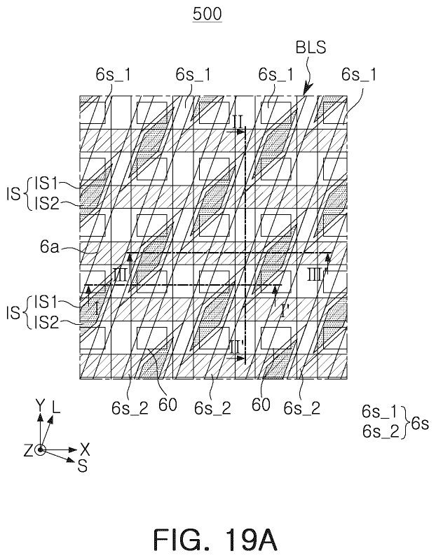

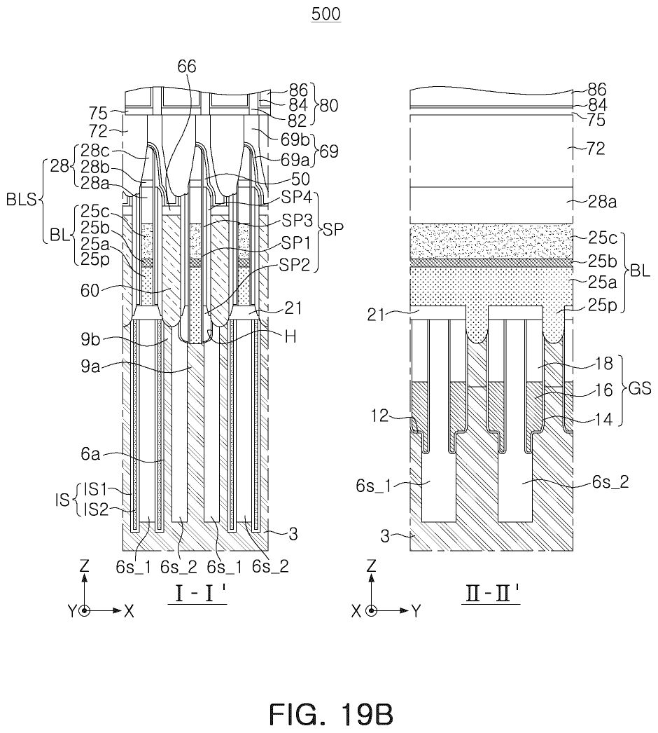

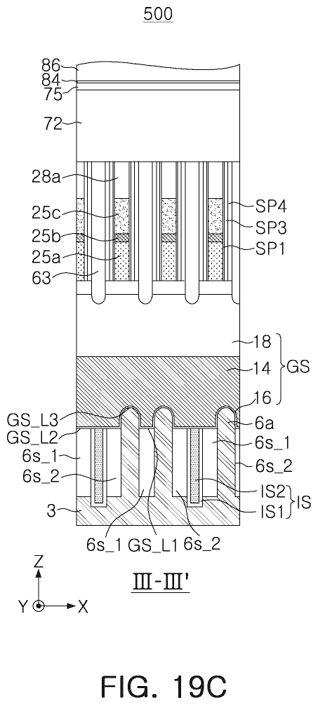

FIGS. 18A to 19C are plan views and vertical cross-sectional views illustrating processes of a method of manufacturing a semiconductor device in order according to an example embodiment. FIGS. 18B and 19B are vertical cross-sectional views taken along lines I-I′ and II-II′ in FIGS. 18A and 19A, respectively. FIGS. 18C and 19C are vertical cross-sectional views taken along III-III′ in FIGS. 18A and 19A, respectively.

Referring to FIGS. 18A to 18C, the insulating structure IS may be formed between the device isolation layers 6s in the process described with reference to FIGS. 16A to 16C. For example, in the process of forming an insulating structure IS, the first device isolation layer 6s_1 and the second device isolation layer 6s_2 may not be etched. Accordingly, the insulating structure IS may not overlap the first device isolation layer 6s_1 and the second device isolation layer 6s_2 in the L-direction. In the plan view, the insulating structure IS may have a rhombic shape. In the plan view, the horizontal width of the first device isolation layer 6s_1 and the second device isolation layer 6s_2 may be constant, and side surfaces of the first device isolation layer 6s_1 and the second device isolation layer 6s_2 may not have a recess region. A portion of the external insulating layer IS1 of the insulating structure IS may extend along surfaces of the first device isolation layer 6s_1 and the second device isolation layer 6s_2. The maximum horizontal width of the insulating structure IS in the S-direction may be the same as the distance between the first device isolation layer 6s_1 and the second device isolation layer 6s_2 adjacent each other, taken in the S-direction. The shape of the insulating structure IS illustrated in FIG. 18A is merely an example, and in some example embodiments, in a plan view, the insulating structure IS may have a circular shape, an elliptical shape, and a rectangular shape.

Referring to FIGS. 19A to 19C, the process described with reference to FIGS. 6A to 6C may be further performed, and a semiconductor device 500 may be manufactured. The semiconductor device 500 may have a structure the same as or similar to that of the semiconductor device 100 in FIGS. 6A to 6C other than the insulating structure IS. In the cross-sectional view, the insulating structure IS may be disposed between the first device isolation layer 6s_1 and the second device isolation layer 6s_2, and horizontal widths in the X-direction or S direction of the first device isolation layer 6s_1 and the second device isolation layer 6s_2 may be the same. In some example embodiments, the insulating structure IS of the semiconductor device 500 may have the same structure as the insulating structure IS described with reference to FIGS. 8A to 9B. For example, the insulating structure IS of the semiconductor device 500 may be a single layer including silicon oxide or silicon nitride.

According to the aforementioned example embodiments, the first device isolation layer may be formed in a process different from the process of forming the second device isolation layer. Accordingly, by forming device isolation layers to have a deeper and finer pattern, a semiconductor device may have a reduced size.

Further, the insulating structure may be formed in a process different from the process of forming the first device isolation layer and the second device isolation layer. Accordingly, an active region may be formed to have a relatively increased size, and contact resistance with a contact plug may be reduced.

While some example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a plurality of device isolation layers extending in a first horizontal direction and spaced apart from each other in a second horizontal direction intersecting the first horizontal direction;
a plurality of active regions between the plurality of device isolation layers and spaced apart from each other in the first horizontal direction;
a plurality of insulating structures between the plurality of active regions; and
a gate structure extending in a third horizontal direction between the first horizontal direction and the second horizontal direction and intersecting the plurality of active regions,
wherein two adjacent side surfaces of each of the plurality of active regions define an acute angle, and
wherein at least a portion of at least one of the plurality of insulating structures is between a corresponding pair of the plurality of active regions and between a corresponding pair of the plurality of device isolation layers and overlaps the corresponding pair of the plurality of active regions in the first horizontal direction.

2. The semiconductor device of claim 1,
wherein the plurality of device isolation layers and the insulating structures extend into a substrate, and
wherein lower surfaces of the insulating structure are at a lower level than lower surfaces of the plurality of device isolation layers.

3. The semiconductor device of claim 1,
wherein the plurality of active regions include first side surfaces and second side surfaces spaced apart from each other in the first horizontal direction, and
wherein the first side surfaces and the second side surfaces are inwardly curved surfaces.

4. The semiconductor device of claim 1, wherein, in a plan view, the plurality of insulating structures have a circular shape.

5. The semiconductor device of claim 1, wherein a portion of at least one of the plurality of insulating structures overlaps one or more of the plurality of device isolation layers in the first horizontal direction.

6. The semiconductor device of claim 1, wherein maximum horizontal width of the plurality of insulating structure are greater than horizontal widths of the plurality of active regions in the second horizontal direction.

7. The semiconductor device of claim 1, wherein the plurality of insulating structures are configured as a single layer.

8. The semiconductor device of claim 1,
wherein the first horizontal direction is a major axis-direction of the plurality of active regions, and
wherein the second horizontal direction is a minor axis-direction of the plurality of active regions.

9. The semiconductor device of claim 1, wherein the plurality of device isolation layers include a plurality of first device isolation layers and a plurality of second device isolation layers alternating in the second horizontal direction.

10. The semiconductor device of claim 9, wherein ends of the plurality of first device isolation layers taken in the first horizontal direction are in a zigzag pattern with ends of the plurality of second device isolation layers taken in the first horizontal direction.

11. The semiconductor device of claim 1, wherein a maximum width of each of the plurality of insulating structures in the second horizontal direction is equal to a distance between two adjacent device isolation layers among the plurality of device isolation layers in the second horizontal direction.

12. The semiconductor device of claim 1, wherein, in a plan view, the plurality of active regions have a rhombic shape.

13. The semiconductor device of claim 12, wherein the plurality of insulating structures intersect the plurality of active regions and the plurality of device isolation layers and extends in a horizontal direction.

14. The semiconductor device of claim 12, wherein, in a plan view, the plurality of insulating structures have a rhombic shape.

15. The semiconductor device of claim 1,
wherein a lower surface of the gate structure includes a first portion in contact with the plurality of device isolation layers and a second portion having a width greater than a width of the first portion and in contact with corresponding ones of the plurality of insulating structures, and
wherein the second portion is at a higher level than the first portion.

16. A semiconductor device, comprising:
a plurality of device isolation layers extending in a first horizontal direction and spaced apart from each other in a second horizontal direction intersecting the first horizontal direction;
a plurality of active regions between the plurality of device isolation layers and spaced apart from each other in the first horizontal direction;
a plurality of insulating structures between the plurality of active regions; and
a gate structure extending in a third horizontal direction between the first horizontal direction and the second horizontal direction and intersecting the plurality of active regions,
wherein two adjacent side surfaces of each of the plurality of active regions define an acute angle,
wherein at least a portion of at least one of the plurality of insulating structures is between a corresponding pair of the plurality of active regions and between a corresponding pair of the plurality of device isolation layers and overlaps the corresponding pair of the plurality of active regions in the first horizontal direction,
wherein the plurality of insulating structures each include an external insulating layer and an internal insulating layer in the external insulating layer, and
wherein the external insulating layer is in contact with a corresponding pair of the plurality of active regions and a corresponding pair of the plurality of device isolation layers.

17. The semiconductor device of claim 16, wherein a horizontal width of the external insulating layer is less than half of a horizontal width of a corresponding one of the device isolation layers in the second horizontal direction.

18. The semiconductor device of claim 16, wherein a lower end of the internal insulating layer is on a lower level than a lower end of the external insulating layer.

19. The semiconductor device of claim 16, wherein the external insulating layer and the internal insulating layer extend in a horizontal direction parallel to each other between a corresponding pair of the plurality of active regions.

20. A semiconductor device, comprising:
a first active region and a second active region extending in a first horizontal direction and spaced apart from each other in the first horizontal direction;
a first device isolation layer and a second device isolation layer spaced apart from each other in a second horizontal direction intersecting the first horizontal direction, the first device isolation layer and the second device isolation layer extending in the first horizontal direction, the first active region and the second active region interposed between the first device isolation layer and the second device isolation layer;
an insulating structure between the first active region and the second active region and in contact with the first active region and the second active region;
a gate structure extending in a third horizontal direction between the first horizontal direction and the second horizontal direction and intersecting the first active region; and
a bitline structure intersecting the first active region and extending in a fourth horizontal direction orthogonal to the third horizontal direction,
wherein a side surface of the first active region in contact with the insulating structure is a curved surface recessed toward a central portion of the first active region, and
wherein at least a portion of the insulating structure is between the first active region and the second active region and between the first device isolation layer and the second device isolation layer, and overlaps the first active region in the first horizontal direction.
